(19) United States
(12) Patent Application Publication
(10) Pub. No.: US 2025/0139853 A1
(43) Pub. Date: May 1, 2025

(54) METHOD FOR GENERATING DOT PATTERN AND COMPUTER-READABLE MEDIUM

(71) Applicant: VIZIONFOCUS INC., Miaoli County (TW)

(72) Inventors: SHIAN-CHI SU, Miaoli County (TW); SHIH-KUO CHEN, Miaoli County (TW); WEI-CHIEH LEE, Miaoli County (TW)

(21) Appl. No.: 18/629,950

(22) Filed: Apr. 9, 2024

(30) Foreign Application Priority Data
Oct. 25, 2023 (TW) 112140861

(51) Int. Cl. G06T 11/20; G06F 30/10

(52) U.S. Cl. CPC G06T 11/20; G06F 30/10; G06T 2210/32

(57) ABSTRACT

Disclosed are a method for generating a dot pattern and a computer-readable medium. The method for generating a dot pattern is applicable to a computer device which executes the method. The method for generating a dot pattern includes: generating a grayscale value weight based on a reference image; inputting a plurality of conversion parameters including a size range of dots, a total number of the dots, and a number of times of iterative operation; generating a plurality of initial random coordinates corresponding to the plurality of dots through a random operation based on the grayscale value weight, the size range of the dots, and the total number of the dots; and performing dot distribution processing on the dots based on the number of times of iterative operation, the grayscale value weight, and the initial random coordinates to generate a dot pattern, where the dot pattern includes the dots.

### FIELD OF THE INVENTION

The present invention relates to a method for generating a dot pattern and a computer-readable medium, and more particularly to a method for converting a reference image based on a plurality of conversion parameters and a random operation (a random algorithm) and generating a dot pattern, where the computer-readable medium stores a program code for executing the method.

### BACKGROUND OF THE INVENTION

In the prior art, for example, dot patterns may be applied to pattern design of contact lenses. The dot patterns include halftone dot patterns, and there are three types of halftone dots: amplitude modulation dots, frequency modulation dots, and composite dots.

The amplitude modulation dots refer to a dot printing technology and may be used to convert an original image (a reference image) into an image in which the center distance of each dot is fixed and the size of the dots is adjustable. By adjusting the size of the dots, the amplitude modulation dots may simulate the color shade of the original image to achieve the desired visual effect. However, with respect to the original image, the amplitude modulation dots have a defect of being unable to accurately present details of a pattern.

The frequency modulation dots refer to another dot printing technology. In the frequency modulation dots, the size of each dot is the same, and the center distance of each dot is adjustable. However, it is not common to apply the frequency modulation dots to the pattern design of the contact lenses at present because the frequency modulation dots are inconvenient for users to design in software operation. In addition, if a large number of dots are used in pursuit of pattern details, it will lead to a problem of production.

The composite dots refer to a newer technology than the first two, which combines the characteristics of the amplitude modulation dots and the frequency modulation dots. However, similar to the frequency modulation dots, it is not common to apply the composite dots to the pattern design of the contact lenses at present because the composite dots are inconvenient for the users to design in software operation.

In summary, the current pattern design of the contact lenses is dominated by the amplitude modulation dots, which can achieve a certain pattern effect, but have limitations in detail presentation. Compared with the amplitude modulation dots, the frequency modulation dots and the composite dots are less used due to being inconvenient for the users to design in software operation. In addition, a dot pattern designed by the frequency modulation dots or the composite dots is actually difficult to put into production and application.

In conclusion, there is still a lack of dot pattern generation technology capable of accurately presenting the details of the original image and convenient for the users to design in software operation.

### SUMMARY OF THE INVENTION

In view of this, the present invention provides a method for generating a dot pattern and a computer-readable medium. A computer device may access the computer-readable medium and execute the method for generating a dot pattern according to the present invention. The dot pattern generated by the method for generating a dot pattern may be applicable to a contact lens. With the method for generating a dot pattern provided by the present invention, a user may provide a pre-designed original image as a reference image to a computer device, the computer device may generate a grayscale value weight corresponding to the reference image based on the reference image, then a plurality of conversion parameters (including, for example, a size range of dots, a total number of the dots, and a number of times of iterative operation) is input, the reference image is converted based on the plurality of conversion parameters and a random operation (a random algorithm), and coordinates of the dots are generated in a random operation manner to generate a dot pattern. Therefore, the user may quickly and conveniently use the original image as the reference image after design of the original image to accurately present details of the original image and generate the dot pattern corresponding to the original image.

The method for generating a dot pattern provided by the present invention is applicable to the computer device and includes: generating a grayscale value weight based on a reference image; inputting a plurality of conversion parameters including a size range of dots, a total number of the dots, and a number of times of iterative operation; generating a plurality of initial random coordinates corresponding to the plurality of dots through a random operation based on the grayscale value weight, the size range of the dots, and the total number of the dots; and performing dot distribution processing on the dots based on the number of times of iterative operation, the grayscale value weight, and the initial random coordinates to generate a plurality of iterative random coordinates, and generating a dot pattern through the iterative random coordinates, where the dot pattern includes the dots.

In an embodiment of the present invention, the method for generating a dot pattern further comprises: storing the dot pattern in a vector image format.

In an embodiment of the present invention, the size range of the dots is 0.001-1 mm in the method for generating a dot pattern.

In an embodiment of the present invention, the total number of the dots ranges from 10 to 10,000 in the method for generating a dot pattern.

In an embodiment of the present invention, the number of times of iterative operation ranges from 0 to 1,000 in the method for generating a dot pattern.

The computer-readable medium provided by the present invention is configured to store a program code including the method for generating a dot pattern as described above, and a processing unit of the computer device can execute the program code.

In summary, according to the method for generating a dot pattern provided by the present invention, the user may use the original image as the reference image after design of the original image to quickly and conveniently generate the coordinates of the dots in a random operation manner based on the plurality of conversion parameters so as to generate the dot pattern. Compared with the prior art, the method for generating a dot pattern provided by the present invention may present the details of the original image more accurately and generate the dot pattern corresponding to the original image.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a block diagram of a computer device provided by an embodiment of the present invention;

FIG. 2 is a flowchart of steps of a method for generating a dot pattern provided by an embodiment of the present invention;

FIG. 3A is a schematic diagram of an original image (a reference image) provided by an embodiment of the present invention; and

FIGS. 3B, 4A, 4B, 5A, 5B, 5C, 6A, 6B, and 6C are schematic diagrams of dot patterns generated by a method for generating a dot pattern according to the present invention.

### DETAILED DESCRIPTION OF PREFERRED EMBODIMENTS

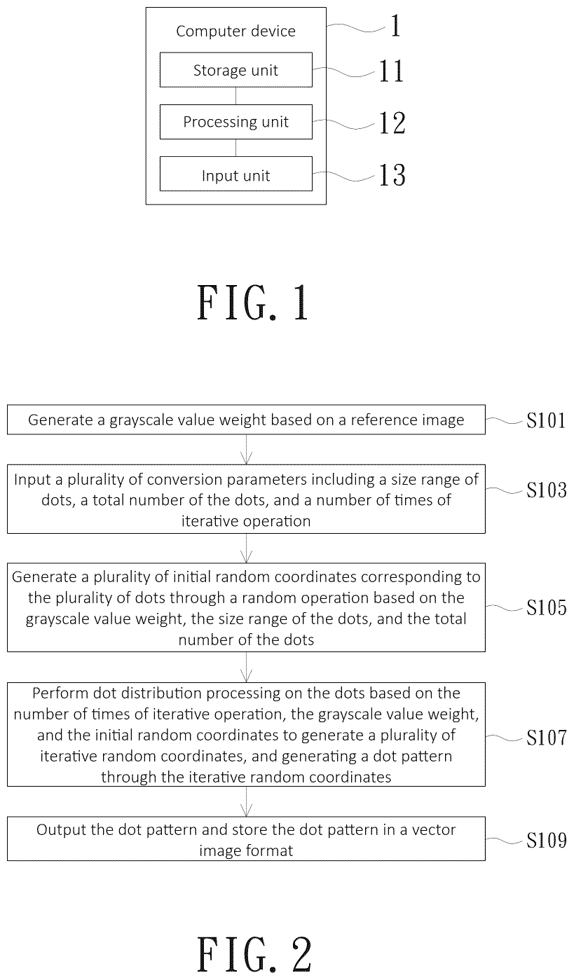

A reference is made to FIG. 1, which is a block diagram of a computer device 1 provided by an embodiment of the present invention.

In this embodiment, the computer device 1 provided by the present invention includes a storage unit 11, a processing unit 12, and an input unit 13. The processing unit 12 is connected to the storage unit 11 and the input unit 13.

In this embodiment, the computer device 1 may access the storage unit 11 (a computer-readable medium) and is configured to execute a method for generating a dot pattern.

In this embodiment, the storage unit 11 may store data such as a reference image, a grayscale value weight, a plurality of conversion parameters (for example, the conversion parameters may include a size range of dots, a total number of the dots, and a number of times of iterative operation), a random operation algorithm, an iterative operation algorithm, dot distribution processing, a program code, and a dot pattern. The storage unit 11 may include a non-volatile memory (NVM) and/or a volatile memory. For example, the storage unit 11 may be a conventional hard disk, a solid-state drive, a memory, a memory card, or another device with the data storage function. The types of storage units 11 listed are only examples, and the present invention is not limited to this.

In this embodiment, the processing unit 12 is a computing device which may access the data stored in the storage unit 11 and perform the algorithm, the program code, and the functions of data transmission and the like. For example, the processing unit 12 may be a single-chip microcomputer (MCU), a central processing unit (CPU), or another device with the same function. The types of processing units listed are only examples, and the present invention is not limited to this.

In this embodiment, a user may input a plurality of conversion parameters through the input unit 13, where the conversion parameters may include a size range of dots, a total number of the dots, and a number of times of iterative operation. For example, the input unit 13 may be an input device such as a keyboard and a mouse, or another device with the same function. The types of input units listed are only examples, and the present invention is not limited to this.

Then, a reference is made to FIG. 2. FIG. 2 is a flowchart of steps of a method for generating a dot pattern provided by an embodiment of the present invention. The method includes the following steps.

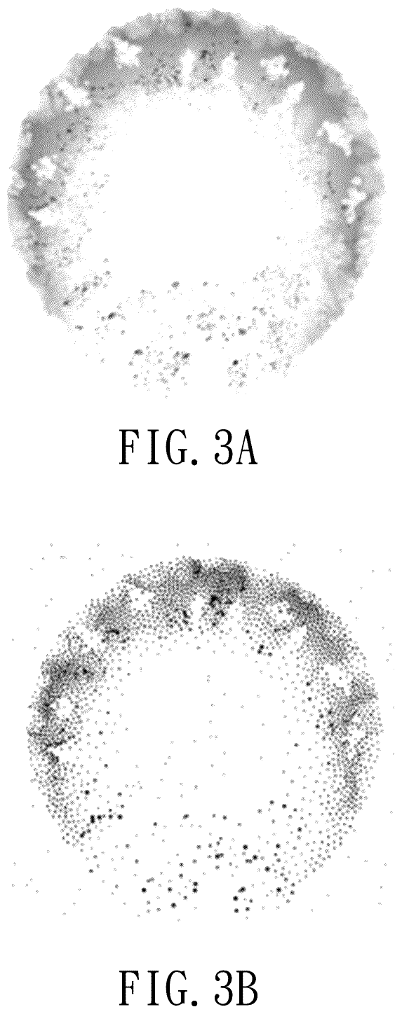

In step S101, a grayscale value weight is generated based on a reference image. A reference is made to FIG. 3A. FIG. 3A is a schematic diagram of an original image (a reference image) provided by an embodiment of the present invention. For example, the user may create a canvas with a size of 2048×2048 pixel resolution in advance through drawing software, and then design the original image in a drawing area of the canvas, where the original image may be freely designed according to user requirements, and a file format may be, for example, a non vector image format such as JPG or PNG. Then, the user may provide the designed original image as the reference image to the computer device 1, and the computer device 1 may generate the grayscale value weight corresponding to each pixel in the reference image. In one embodiment, the computer device 1 may use a plurality of adjacent pixels in the reference image as a pixel group and generate the grayscale value weight corresponding to the pixel group. In one embodiment, the reference image may be a color image, and the computer device 1 may perform grayscale value conversion on the reference image first and then regenerate the grayscale value weight.

In step S103, a plurality of conversion parameters are input, where the conversion parameters include a size range of dots, a total number of the dots, and a number of times of iterative operation. The user may input the plurality of conversion parameters through the input unit 13 to complete parameter setting. The overall structure and detail features of the generated dot pattern may be further controlled through adjustment of the parameters. For example, the size range of the dots may be 0.001-1 mm, the total number of the dots may range from 10 to 10,000, and the number of times of iterative operation may range from 0 to 1,000.

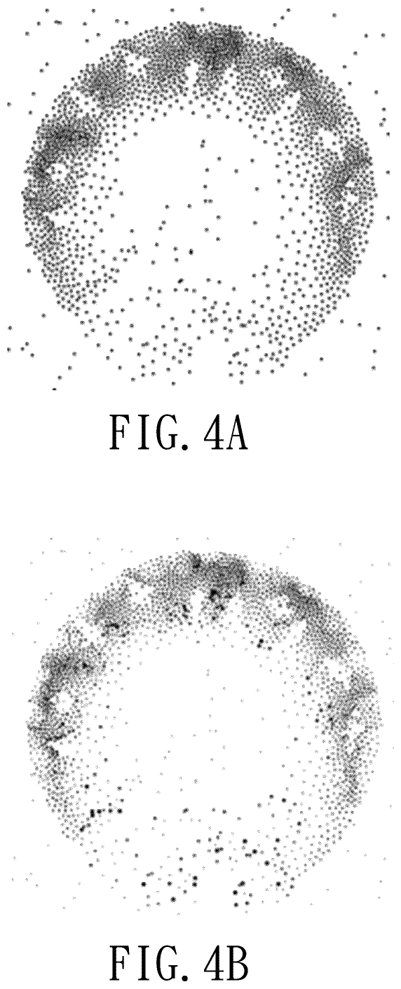

For the size range of the dots, a reference is made to FIG. 4A and FIG. 4B. In the case of setting the total number of the dots to 2,000 and the number of times of iterative operation to 10, FIG. 4A shows a pattern generated only using dots with a single size of 0.05 mm, and FIG. 4B shows a pattern generated using dots with a size range of 0.05-0.15 mm. It can be observed that FIG. 4B has a significant improvement in contrast and fineness. Compared with the dots with a single size, the dots with a given size range are more conducive to improving the contrast, thereby making the dot pattern closer to the reference image.

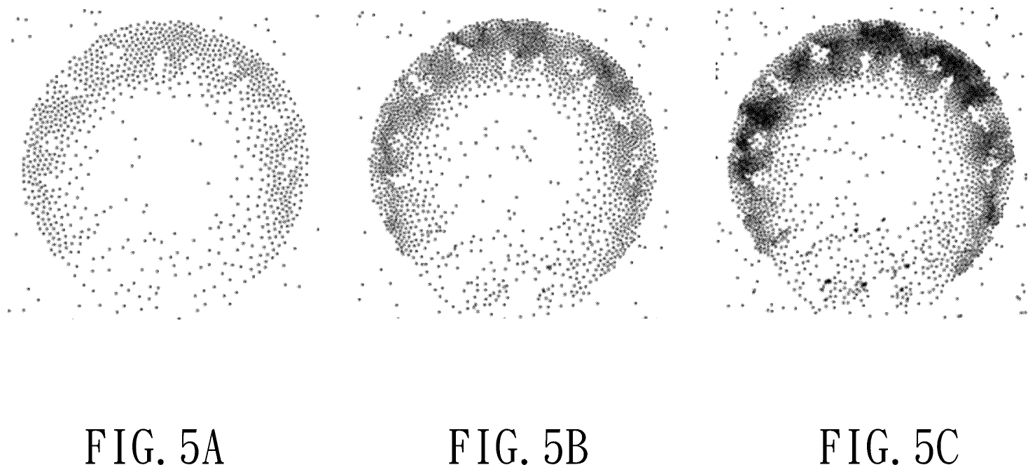

For the total number of the dots, a reference is made to FIG. 5A to FIG. 5C. In the case of setting the size range of the dots to 0.05 mm and the number of times of iterative operation to 10, FIG. 5A to FIG. 5C are used to compare the effects during placement of 1,000, 2,000, and 3,000 dots, and show the impacts of the total number of the dots on the generated dot pattern. The increase in the total number of the dots is more helpful in presenting details of the original image.

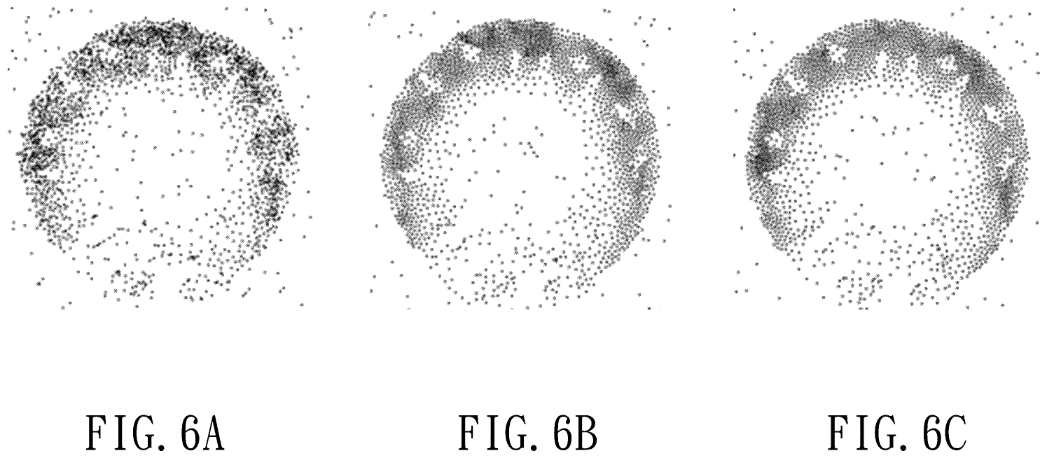

For the number of times of iterative operation, a reference is made to FIG. 6A to FIG. 6C. The number of times of iterative operation affects a distribution state of the dots. In the case of the size range of the dots being 0.05 mm and the total number of the dots being 2,000, FIG. 6A to FIG. 6C are used to compare and show the effects during 0, 10, and 20 times of iterative operation (dot distribution processing), respectively. In the case of the same size range of the dots and the same total number of the dots, it can be obviously seen from FIG. 6A and FIG. 6B that dot distribution is adjusted to be similar to that in the reference image through the iterative operation (dot distribution processing). In contrast, dot distributions in FIG. 6B and FIG. 6C are not much different, which is mainly because 10 times of iterative operation (dot distribution processing) is enough to adjust the positions of the dots to constant values, so even if the iterative operation (dot distribution processing) is performed for multiple times later, there will not be much difference in dot distribution.

In step S105, a plurality of initial random coordinates corresponding to the plurality of dots are generated through a random operation based on the grayscale value weight, the size range of the dots, and the total number of the dots. For example, the random operation may preliminarily generate a plurality of random coordinates corresponding to the plurality of dots within a specified range based on the grayscale value weight by using any random number generation algorithm, and these random coordinates are used as the initial random coordinates of the random dots. These random coordinates have high randomness and uniformity, causing the generated dot pattern to exhibit random number characteristics. In this embodiment, grayscale values of the reference image are mainly regarded as a probability distribution, and the coordinates of the dots are generated by using the random operation based on the size range of the dots and the total number of the dots input by the user and are used as the initial random coordinates for subsequent dot distribution processing, such that the subsequent dot distribution processing can adjust the positions of the dots to be close to those in the reference image more quickly.

In step S107, dot distribution processing is performed on the dots based on the number of times of iterative operation, the grayscale value weight, and the initial random coordinates to generate a plurality of iterative random coordinates, and a dot pattern is generated through the iterative random coordinates. In this embodiment, the processing unit 12 may perform dot distribution processing for multiple times based on the grayscale value weight, the number of times of iterative operation input by the input unit 13, and the initial random coordinates (and/or the iterative random coordinates) to generate the plurality of iterative random coordinates, and then generate the dot pattern through the iterative random coordinates, thereby adjusting the positions of the dots to be close to those in the reference image. The iterative random coordinates refer to coordinates obtained by performing dot distribution processing (i.e., iterative operation) for multiple times based on the initial random coordinates. In one embodiment, the dot distribution processing may further include random distribution processing and uniform distribution processing. The user may select the random distribution processing and/or the uniform distribution processing based on a preferred dot presentation mode, to generate a dot pattern closer to preferences of the user.

In step S109, the dot pattern is output and stored in a vector image format. The generated random dot pattern is output in a digital image file format or other supported vector file formats for subsequent post-processing, modification, or saving. Such output format has broad compatibility and scalability, making it easy to apply to various design tools and output media. For example, the dot pattern may be output in a vector image format such as a scalable vector graphics (SVG) file for further modification later.

The method for generating a dot pattern according to the present invention is different from composite dots. The dot pattern generated by the method for generating a dot pattern according to the present invention has high randomness and complexity, and may be flexibly adjusted based on different design requirements and application scenarios. The method for generating a dot pattern according to the present invention may be applicable to various software applications and image design tools, provides a simple and effective creative tool, and provides the user with a larger creative space. The method for generating a dot pattern according to the present invention has broad application value in the field of contact lens pattern design, and brings more design possibilities and creative inspirations to the user.

In summary, according to the method for generating a dot pattern provided by the present invention, the user may use the original image as the reference image after design of the original image to quickly and conveniently generate the coordinates of the dots in a random operation manner based on the plurality of conversion parameters so as to generate the dot pattern. Compared with the prior art, the method for generating a dot pattern provided by the present invention may present the details of the original image more accurately and generate the dot pattern corresponding to the original image.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for generating a dot pattern applicable to a computer device, the method for generating a dot pattern comprising:
generating a grayscale value weight based on a reference image;
inputting a plurality of conversion parameters including a size range of dots, a total number of the dots, and a number of times of iterative operation;
generating a plurality of initial random coordinates corresponding to the plurality of dots through a random operation based on the grayscale value weight, the size range of the dots, and the total number of the dots; and
performing dot distribution processing on the dots based on the number of times of iterative operation, the grayscale value weight, and the initial random coordinates to generate a plurality of iterative random coordinates, and generating a dot pattern through the iterative random coordinates, wherein the dot pattern comprises the dots.

2. The method for generating a dot pattern according to claim 1, further comprising:
storing the dot pattern in a vector image format.

3. The method for generating a dot pattern according to claim 1, wherein the size range of the dots is 0.001-1 mm.

4. The method for generating a dot pattern according to claim 1, wherein the total number of the dots ranges from 10 to 10,000.

5. The method for generating a dot pattern according to claim 1, wherein the number of times of iterative operation ranges from 0 to 1,000.

6. A computer-readable medium storing a program code which is executed by a processing unit,
wherein the program code comprises the method for generating a dot pattern according to any one of claims 1 to 5.
